(19) United States
(12) Patent Application Publication
(10) Pub. No.: US 2021/0089741 A1
(43) Pub. Date: Mar. 25, 2021

(54) Thin-Film Transistor Optical Imaging System with Integrated Optics for Through-Display Biometric Imaging

(71) Applicant: Apple Inc., Cupertino, CA (US)

(72) Inventors: Po-Chun Yeh, Sunnyvale, CA (US); Yujia Zhai, Fremont, CA (US); Yuan Chen, Campbell, CA (US); Mohammad Yeke Yazdandoost, Santa Clara, CA (US); Giovanni Gozzini, Berkeley, CA (US); Chia Hsuan Tai, San Jose, CA (US); Jiun-Jye Chang, Cupertino, CA (US); Ching-San Chuang, Sunnyvale, CA (US)

(21) Appl. No.: 17/003,636

(22) Filed: Aug. 26, 2020

Related U.S. Application Data
(60) Provisional application No. 62/904,211, filed on Sep. 23, 2019.

(51) Int. Cl. G06K 9/00; G06F 3/044; G06K 9/20; H01L 27/32; H01L 27/15

(52) U.S. Cl. CPC G06K 9/0004; G06F 3/044; G06K 9/209; H01L 27/3244; H01L 27/1462; H01L 27/3234; H01L 27/156; G06K 9/00604; H01L 27/323

(57) ABSTRACT

Systems and methods for through-display imaging. An optical imaging sensor is positioned at least partially behind a display and is configured to emit visible wavelength light at least partially through the display to illuminate an object, such as a fingerprint or a retina, in contact with or proximate to an outer surface of the display. Surface reflections from the object traverse the display stack and are received and an image of the object can be assembled.

### CROSS-REFERENCE TO RELATED APPLICATION

This application is a nonprovisional of and claims the benefit under 35 U.S.C. 119(e) of U.S. Provisional Patent Application No. 62/904,211, filed Sep. 23, 2019, the contents of which are incorporated herein by reference as if fully disclosed herein.

### FIELD

Embodiments described herein relate to optical biometric imaging through an electronic device display and, in particular, to optical fingerprint or retina imaging systems with integrated optics configured for use behind a display of an electronic device.

### BACKGROUND

An electronic device display (a “display”) is typically formed from a stack of functional and structural layers (a “display stack”) that is attached to, or otherwise disposed below, a protective cover. In many conventional implementations, the protective cover defines an exterior surface of a housing of the electronic device that incorporates the display. For increased contrast, a conventional display stack is intentionally designed to be opaque.

An electronic device can also include an optical imaging system. Certain optical imaging systems, such as front-facing cameras or ambient light sensors, are often configured to be attached to, or otherwise disposed below, the same exterior surface of the housing as the display. As a result of this design constraint (and the opacity of a conventional display stack), an electronic device incorporating both a display and a “front-facing” optical imaging system is typically constructed with a protective cover that extends a distance beyond a periphery of the display to reserve space to accommodate the front-facing optical imaging system. However, this conventional solution (1) undesirably increases the apparent size of a bezel region circumscribing the display and (2) undesirably increases the size and volume of the housing of the electronic device.

### SUMMARY

Embodiments described relate to optical sensing systems configured to be positioned behind a light-emitting element disposed on a transparent substrate. More specifically, in these embodiments, the light-emitting element is oriented to emit light normal to a first surface of the transparent substrate. The optical sensing system further includes a second substrate, which may be transparent or otherwise, that is coupled to a second surface of the first substrate opposite the first surface.

In these embodiments, the second substrate includes a photodiode oriented to collect light normal to the second surface. Such light may be incident to the transparent substrate and may pass through the transparent substrate to exit the second surface along a path toward the photodiode.

In these embodiments, the optical sensing system further includes a collimator disposed over and aligned with the photodiode, positioned between the photodiode and the second surface. In addition, the optical sensing system includes a convex microlens disposed over, and aligned with, the collimator. More specifically, the microlens is positioned between the collimator and the second surface of the transparent substrate. In this construction, the microlens is configured to focus light incident to the microlens into the collimator and toward the photodiode.

As a result of this construction, at least a portion of light emitted from the light-emitting element may be light that has reflected from a surface an object (e.g., finger, stylus, and so on) proximate to the transparent substrate. At least a portion of this reflected light can pass through the transparent substrate (e.g., through a region of the transparent substrate adjacent to, or otherwise peripheral to, the light-emitting element), the microlens, and the collimator, and may be absorbed by the photodiode.

Embodiments described herein can include a configuration in which the photodiode, the collimator, and the microlens are formed by a thin-film transistor manufacturing process.

Embodiments described herein can include an infrared cut filter disposed between the collimator and the photodiode or between the collimator and the microlens or between the microlens and the second surface. In further embodiments, the transparent substrate can include an infrared cut filter. In other cases, an infrared cut filter may not be required.

Embodiments described herein can include a configuration in which the light-emitting element is one element of an array of light-emitting elements disposed on the transparent substrate. In these embodiments, the array of light-emitting elements can be pixels of an electronic device display.

Embodiments described herein relate to an electronic device configured to capture an image of a portion of an object touching a surface of the electronic device, such as a finger or a stylus. In these and related embodiments, the electronic device includes a transparent outer cover (also referred to as a cover glass, a cover, a protective outer cover, a housing surface, and the like) defining an interface surface. The interface surface is operable to receive a touch from the object.

The electronic device further includes a light-emitting layer positioned below the transparent outer cover. The light-emitting layer includes a first thin-film transistor layer with a transparent substrate and an array of pixels disposed in a pattern on the transparent substrate. The array of pixels (also referred to as light-emitting elements, light emitting diodes, organic pixels, and so on) is configured to emit light through the transparent outer cover to illuminate the contact area, defined to be a portion of the object in contact with (e.g., wetting to) the interface surface during the touch.

In these example embodiments, the electronic device further includes an optical imaging sensor coupled to a lower surface of the first thin-film transistor layer. The optical imaging sensor includes a second thin-film transistor layer with a conductive trace, a photosensitive element (e.g., photodiode, organic photodiode, micro solar device, phototransistor, and so on) coupled to the second thin-film transistor layer and electrically coupled to the conductive trace, an infrared cut filter coupled to the photosensitive element (configured to reflect and/or absorb infrared light passing through the transparent substrate between pixels of the array of pixels), a collimator array formed over the infrared cut filter (configured to narrow a field of view of the photosensitive element), and a microlens array formed over the collimator array. In particular, each respective microlens of the array of microlenses is configured to focus light incident to that respective microlens into a respective one collimator of the collimator array. In these constructions, the microlens array is coupled to the lower surface of the first thin-film transistor layer by an adhesive.

As a result of this architecture, at least a portion of light emitted from the light-emitting layer (e.g., from at least one pixel of that layer) can reflect from the contact area, pass through the transparent substrate (e.g., between pixels of the array of pixels), is focused into a respective one collimator of the array of collimators by a respective one microlens of the array of microlenses, and can be, thereafter, absorbed by the photosensitive element.

Embodiments described here can include a configuration in which the object engaging, touching, wetting to, or otherwise interfacing the interface surface is a finger. In these examples, the light reflected from the finger and absorbed by the photosensitive element may be used to construct a fingerprint image or a retina image.

Embodiments described here can include a configuration in which the light-emitting layer is a display, such as an organic light-emitting diode display or a micro light-emitting diode display.

In some examples, the collimator array comprises an opaque layer (e.g., ink, a reflective backing, a metal layer, a non-conducting layer, and the like and so on) disposed over the photosensitive element and an array of apertures defined through the opaque layer, each aligned along a common axis. In some cases, the apertures defined through the opaque layer of the collimator can be aligned normal to the photosensitive element, but this may not be required. In other cases, the apertures defined through the opaque layer of the collimator can be defined at an angle relative to normal to the photosensitive element.

In these and related embodiments, a touch-sensitive layer (or a force-sensitive layer) can be disposed between the transparent outer cover and the light-emitting layer. An example touch-sensitive layer is a capacitive touch sensor.

Still further embodiments described herein relate to an optical sensing system for capturing light incident to a display of an electronic device. In these examples, the optical imaging system includes a thin-film transistor substrate coupled to a rear surface of the display. The rear surface of the display is opposite a front surface of the display from which light is emitted by the display. The optical sensing system further includes an array of photosensitive elements, each coupled to the thin-film transistor substrate. More specifically, each photosensitive element of the array is positioned between the thin-film transistor substrate and the rear surface of the display and is oriented to collect light incident to the front surface of the display.

Such embodiments further include a collimator disposed over the photodiode between the photodiode and the rear surface of the display. In addition, the optical imaging system further includes a microlens disposed over the collimator and positioned between the collimator and the rear surface.

As a result of this construction, light emitted from the display can reflect from a finger proximate to the front surface of the display. In this manner, at least a portion of the reflected light can pass through the display, the microlens, and the collimator, and may be collected by the photodiode to image a portion of a fingerprint or an image of a retina.

Related embodiments include a flexible circuit communicably coupling the thin-film transistor layer to a processor of the electronic device.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1A depicts an electronic device that can incorporate a display stack suitable for through-display imaging.

FIG. 1B depicts a simplified block diagram of a portion of the electronic device of FIG. 1A.

FIGS. 2A-2B depict example simplified block diagrams of a cross-section of FIG. 1A, taken through line A-A, depicting optical imaging systems such as described herein.

FIG. 3 depicts an example simplified cross-section of a display stack incorporating an optical imaging system, such as described herein.

FIG. 4A depicts an example cross-section of a collimator array of an optical imaging system, such as described herein.

FIG. 4B depicts an example cross-section of another example collimator array of an optical imaging system, such as described herein.

FIG. 4C depicts an example cross-section of another example collimator array of an optical imaging system, such as described herein.

FIG. 5A depicts an example arrangement of microlenses of an optical imaging system, such as described herein.

FIG. 5B depicts another example arrangement of microlenses of an optical imaging system, such as described herein.

FIG. 6 is a simplified flow chart depicting example operations of a method of capturing an image of an object touching a display, such as described herein.

FIG. 7 is a simplified flow chart depicting example operations of a method of manufacturing an optical imaging system with integrated optics, such as described herein.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Similarly, certain accompanying figures include vectors, rays, traces, and/or other visual representations of one or more example paths, which may include reflections, refractions, diffractions, and so on, through one or more mediums, that may be taken by one or more photons originating from one or more light sources shown or, in some cases, omitted from, the accompanying figures. It is understood that these simplified visual representations of light are provided merely to facilitate an understanding of the various embodiments described herein and, accordingly, may not necessarily be presented or illustrated to scale or with angular precision or accuracy, and, as such, are not intended to indicate any preference or requirement for an illustrated embodiment to receive, emit, reflect, refract, focus, and/or diffract light at any particular illustrated angle, orientation, polarization, color, or direction, to the exclusion of other embodiments described or referenced herein.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein reference an electronic device that includes a display, or other light-emitting layer, and an optical imaging system configured to capture light incident to a surface of the display through which light is emitted by the display. The optical imaging system can be manufactured using the same or a similar thin-film transistor manufacturing process employed to manufacture the display. As a result, imaging optics assisting the optical imaging system can be formed directly over (and, thus, precisely and accurately aligned with) light-sensitive elements of the optical imaging system.

The optical imaging system is configured to operate in the visible wavelength band and is positioned on a rear surface of, and/or integrated within, an active display area of the display of the electronic device. As used herein, the phrase “rear surface” of an active display area of a display refers to a surface of a display opposite a surface from which light is emitted by that display, which is referred to herein as the “front surface” of the display.

In these constructions, the optical imaging system or an electronic device incorporating the optical imaging system can instruct or otherwise initiate a process to cause the display of the electronic device to generate light in order to illuminate an object, or part of an object, in contact with or proximate to the front surface of the display. As a result, at least a portion of the light emitted by the display may be reflected from an external surface (or, in some cases, an internal surface) of the object, and, thereafter, redirected incident to the front surface of the display. In turn, at least a portion of this reflected light may pass through a substantially transparent region of the display, such as between adjacent or nearby pixels disposed on a transparent substrate.

This reflected light, having passed through the display, can be collected by the optical imaging system positioned on and/or coupled to the rear surface of the display. In particular, for embodiments described herein, the optical imaging system includes an array of microlenses positioned on the rear surface of the display. Each microlens of the array of microlenses is oriented and configured to focus light passing through the display into a respective one collimator among an array of collimators. Each respective collimator is configured to (1) guide light that is directed generally parallel to (e.g., within a selected acute angle relative to) a central axis of that collimator onto a photosensitive surface of a photodiode and (2) to reflect and/or absorb light all other light within the collimator away from the photosensitive surface of the photodiode.

As a result of this construction, light reflected from an object nearby a front surface of the display that passes through the display and is oriented generally parallel to normal to the front surface of the display, can be received and absorbed by a photodiode. Thereafter, an electrical signal generated by, or modified by, the photodiode as a result of absorbing light can be received by a circuit or processor that, in turn, can measure or determine one or more characteristics of light received by that photodiode. Example characteristics include, but are not limited to: brightness; color; spectral content; frequency; wavelength; and the like. These examples are not exhaustive and, in other embodiments, other characteristics of light, and/or changes over time of one or more characteristics of light, can be measured, tracked, or otherwise captured by a circuit or processor, such as described herein. For simplicity of description, the embodiments that follow reference an optical imaging system configured to detect and measure or determine brightness of light received by a photodiode. It may be appreciated, however, that this is merely one example and that, in other embodiments, other characteristics or combinations of characteristics can be used.

In many embodiments described herein, an optical imaging system includes an array of photodiodes (or, more generally, an array of photosensitive elements) arranged in a pattern below a rear surface of a display. Each photodiode of the array can be associated with a respective one or more collimators, each in turn associated with a respective one microlens oriented to face the rear surface of the display to capture light that passes through the display, such as described above.

In these embodiments, light absorbed by each photodiode of the array can be measured and assembled, by circuit and/or a processor such as described above, into a two-dimensional image of an exterior surface of an object proximate to, or in contact with, the front surface of the display.

In this manner, more generally and broadly, embodiments described herein facilitate through-display imaging of an object nearby the front surface of a display. The image or image(s) captured by an optical imaging system, such as described herein, can have any suitable resolution, can be in color or otherwise, and can be used for any suitable purpose by an electronic device incorporating that optical imaging system. Example purposes include, but are not limited to: imaging of a fingerprint touching the front surface of a display; imaging of a retina proximate to the display; proximity sensing; optical communication; image or video capture; touch input sensing and locating; touch input gesture sensing; and the like. For simplicity of description, the embodiments that follow reference an example implementation in which an optical imaging system is leveraged by an electronic device to capture images of a fingerprint touching an external surface, such as a protective outer layer (also referred to as a “cover glass”), above an active display area of a display of that electronic device. It may be appreciated, however, that this is merely one example and that, in other embodiments, an optical imaging system can be leveraged by an electronic device to capture images or other optical information in any other suitable manner.

In certain embodiments, the electronic device includes a housing which supports and encloses a display having an active display area oriented to emit light through a transparent portion of the housing or a cover glass coupled to a body portion of that housing. An optical imaging system, such as described herein, can be adhered, affixed, formed onto, or otherwise coupled to a rear surface of that display opposite at least a portion of the active display area, within the housing of the electronic device.

As a result of this construction, when a user of the electronic device touches the housing above the active display area and above the optical imaging system (for example to interact with content shown on the display), the optical imaging system can obtain one or more two-dimensional images of the user's fingerprint and/or determine one or more other characteristics or properties of that user's finger. For example, the optical imaging system can be configured to, without limitation: obtain an image or a series of sequential images of the user's fingerprint; determine a vein pattern of the user; determine blood oxygenation of the user; determine the user's pulse; determine whether the user is wearing a glove; determine whether the user's finger is wet or dry; and so on.

As noted above, an optical imaging system (such as described herein) can be used by an electronic device for any suitable imaging, sensing, or other data aggregation purpose without contributing to the size of a bezel region surrounding an apparent active display area of a display of that electronic device. Example uses include, but are not limited to: ambient light sensing; proximity sensing; depth sensing; receiving structured light; optical communication; proximity sensing; position-finding; biometric imaging (e.g., fingerprint imaging, iris imaging, facial recognition, vein imaging, and so on); determining optical, physical, or biometric properties (e.g., reflection spectrum, absorption spectrum, and so on); and the like.

In some embodiments, multiple discrete optical imaging systems can be associated with different regions of the same active display area of the same display. For example, a first optical imaging system can be disposed relative to a lower portion of a display and a second optical imaging system can be disposed behind an upper portion of the same display.

For simplicity of description, many embodiments that follow reference an example construction in which a single optical imaging system is positioned at least partially behind a lower region or portion of an active display area of a display of an electronic device. It may be appreciated, however, that these embodiments described herein, together with equivalents thereof, may be altered or adjusted to incorporate any suitable number of optical imaging systems positioned in a variety of locations relative to an active display area or a non-display surface of an electronic device and configured for the same or different imaging, sensing, or data aggregation purposes. For example, an optical imaging system may additionally or alternatively be configured to operate with infrared light or ultraviolet light. In such examples, the active display area can include infrared light-emitting elements or ultraviolet light-emitting elements adjacent to visible light-emitting elements of the active display area. In other cases, the optical imaging system can include one or more light-emitting elements configured to emit light at a suitable wavelength through a rear surface of a display.

For example, in some embodiments, an optical imaging system extends across an entire active display area such that a touch to any region of the active display area can be imaged by the optical imaging system. In another example, a first optical imaging system positioned relative to a first region of an active display area of a display of an electronic device may be configured to obtain an image of a fingerprint of a finger of a user of that electronic device whereas a second optical imaging system positioned relative to a second region of the active display area may be configured to obtain a retinal image of the user's eye.

In many embodiments, an optical imaging system, such as described herein, can be manufactured using thin-film transistor manufacturing techniques or, more generally, can be manufactured using semiconductor processing methods. In these embodiments, optics associated with a photodiode (e.g., collimators, microlenses, light filters, and so on) can be formed in the same process and the photodiode itself. As a result of this manufacturing technique, alignment between micro-scale optics and photosensitive surfaces of photodiodes can be assured. In these embodiments, a thin-film transistor layer, including one or more electrical traces, can be formed onto a rigid or flexible substrate that may be transparent or opaque. An array of photodiodes can be formed onto the thin-film transistor layer.

One or more collimators can be formed and cured onto the photosensitive surface(s) of each photodiode of the array of photodiodes. Microlenses, typically taking a convex shape, can be formed and cured over each collimator. This stack, from the thin-film transistor layer substrate to the microlenses, can thereafter be adhered to a rear surface of a display, below an active display area region of that display exhibiting at least partial transparency (e.g., regions between adjacent or nearby pixels are left transparent).

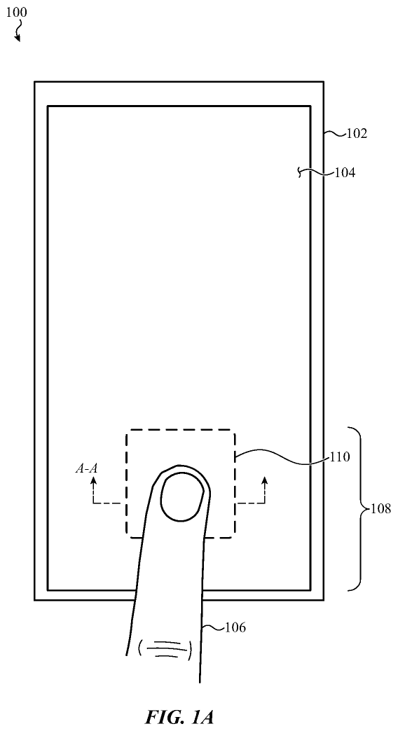

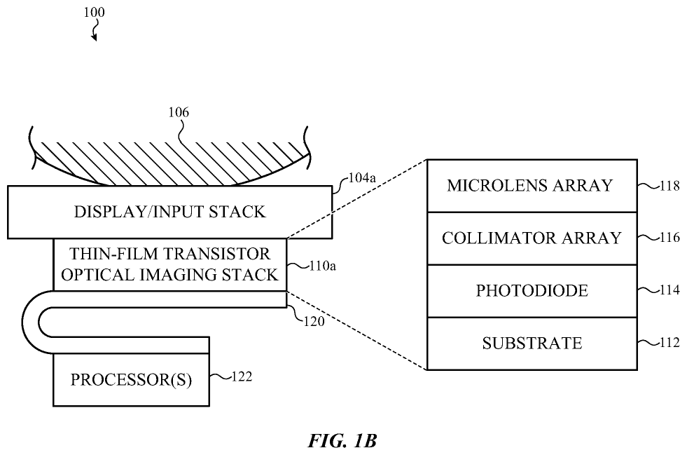

These foregoing and other embodiments are discussed below with reference to FIGS. 1A-7. However, those skilled in the art will readily appreciate that the detailed description given herein with respect to these figures is for explanatory purposes only and should not be construed as limiting.

FIG. 1A depicts an electronic device 100, including a housing 102 that encloses a stack of multiple layers, referred to as a “display stack,” that cooperate to define a digital display configured to render visual content to convey information to, to solicit touch or force input from, and/or to provide entertainment to a user of the electronic device 100.

The display stack can include layers or elements such as, in no particular order: a touch input layer; a force input layer; a haptic output layer; a thin-film transistor layer; an anode layer; a cathode layer; an organic layer; an encapsulation layer; a reflector layer; a stiffening layer; an injection layer; a transport layer; a polarizer layer; an anti-reflective layer; a liquid crystal layer; a backlight layer; one or more adhesive layers; a compressible layer; an ink layer; a mask layer; and so on.

For simplicity of description, the embodiments that follow reference a display stack implanted with an organic light emitting diode display technology and can include, among other layers: a reflective backing layer; a thin-film transistor layer; an encapsulation layer; and an emitting layer. It is appreciated, however, that this is merely one illustrative example implementation and that other displays and display stacks can be implemented with other display technologies, or combinations thereof. An example of another display technology that can be used with display stacks and/or displays such as described herein is a micro light emitting diode display.

The display stack also typically includes an input sensor (such as a force input sensor and/or a touch input sensor) to detect one or more characteristics of a user's physical interaction with an active display area 104 defined by the display stack of the display of the electronic device 100. The active display area 104 is typically characterized by an arrangement of individually-controllable, physically-separated, and addressable pixels or subpixels distributed at one or more pixel densities and in one or more pixel or subpixel distribution patterns. In a more general phrasing, the active display area 104 is typically characterized by an arrangement of individually-addressable discrete light-emitting regions or areas that are physically separated from adjacent or other nearby light-emitting regions. In many embodiments, the light-emitting regions defining the active display area 104 are disposed onto, or formed onto, a transparent substrate that may be flexible or rigid. Example materials that can form a transparent substrate, such as described herein, include polyethylene terephthalate, glass, sapphire, or other forms of corundum. In other cases, a partially opaque substrate can be used; in such embodiments, at least a portion of the substrate between the pixels defined thereon may be partially or entirely optically transparent.

In addition, example input characteristics that can be detected by an input sensor of the electronic device 100, which can be disposed above or below a display stack, or, in other cases, can be integrated with a display stack, can include, but are not limited to: touch location; force input location; touch gesture path, length, duration, and/or shape; force gesture path, length, duration, and/or shape; magnitude of force input; number of simultaneous force inputs; number of simultaneous touch inputs; and so on.

As a result of these constructions, a user 106 of the electronic device 100 may be encouraged to interact with content shown in the active display area 104 of the display by physically touching and/or applying a force with the user's finger to the input surface above an arbitrary or specific region of the active display area 104.

In these embodiments, as with other embodiments described herein, the display stack is additionally configured to facilitate through-display imaging. In particular, the display stack further includes and/or is coupled to an optical imaging system positioned relative to a rear surface of the display stack. As a result of this construction, the optical imaging system can be operated by the electronic device 100 to capture a two-dimensional image of light incident to an area of the front surface of the display stack. For example, the optical imaging system of the electronic device can be operated by the electronic device 100 to capture an image of a fingerprint when the user 106 touches the display to interact with content shown in the active display area 104.

More specifically, in one example, the display stack defines an imaging aperture or an array of discrete and separated imaging apertures (not shown) through a backing layer or other opaque layer defining a rear surface of the display stack, thereby permitting light to travel through the display stack from the front surface to the rear surface between two or more organic light emitting diode subpixels or pixels (herein, “inter-pixel” regions). In some cases, the imaging aperture takes a rectangular shape and is disposed on a lower region 108 of the active display area 104, but this may not be required.

In other cases, the imaging aperture takes a circular or oval shape and is disposed in a central region of the active display area 104. Typically, the imaging aperture is larger than the fingerprint of the user 106, but this may not be required and smaller apertures may be suitable. For example, in some embodiments, the backing layer may be omitted entirely; the imaging aperture may take the same size and shape as the active display area 104.

In these embodiments, the optical imaging system is positioned at least partially below the imaging aperture in order to collect and measure or determine light directed through the inter-pixel regions of the display stack, traveling through the display stack in a direction substantially opposite to a direction of travel of light emitted by the display stack. More specifically, the optical imaging system is configured to capture light incident to the front surface of the display that passes through an inter-pixel region of the display stack, and exits the rear surface of the display. In many embodiments, the optical imaging system can be configured to operate with the display such that the display emits light in order to illuminate an object in contact with the front surface of the display (or an outer protective layer covering the front surface of the display). In these examples, light emitted from one or more light-emitting regions of the display (e.g., pixels) can be reflected from the surface of the object and, thereafter, can travel through the display stack, through an imaging aperture, and can be collected/absorbed by at least one photosensitive area or region (e.g., a photodiode) of the optical imaging system. In some cases, the display can be configured to emit light in a particular region of the active display area 104 by coordinating with an input sensor associated with the display. For example, as noted above, the electronic device 100 can include a touch input sensor. In this example, the touch input sensor can be configured to detect an area of wetting (herein “contact area”) of the fingerprint of the user 106. Once the contact area is detected, the display can be configured to illuminate that contact area with a particular wavelength, brightness, or other pattern of light. For example, in some embodiments, the display can be configured to illuminate the contact area with a blue color of a particular brightness. In other cases, the display can be configured to illuminate the contact area with a green color of a particular brightness. In still other cases, the display can be configured to display a pattern or other two-dimensional image below the contact area. In still further examples, the display can be configured to illuminate the contact area with a time-varying pattern or color. It may be appreciated that the foregoing examples are not exhaustive; a display such as described herein can coordinate and/or otherwise cooperate with a touch input sensor of an electronic device in any suitable manner to illuminate one or more detected contact areas (and/or other areas associated therewith, such as areas peripheral to a detected contact area) in any suitable manner. For simplicity of description, the phrase “illumination operation” is used herein to describe a function or operation of a display of an electronic device that results in a particular area or subarea of an active display area to emit light in a particular or selected manner in order to illuminate an object in contact with or otherwise proximate to a front surface of that display or, alternatively, an outer surface of a protective outer layer that covers the front surface of the display.

As noted above, an illumination operation can be instructed by an optical imaging system, such as the optical imaging system described in reference to the electronic device 100. Also as noted above, an optical imaging system can instruct, or otherwise cause to occur, an illumination operation for any suitable imaging or light detection purpose. In some examples, the optical imaging system can be configured to obtain an image of a retina of the user 106. In this example, the illumination operation can be instructed by the optical imaging system once a user's eyes are within a threshold distance of the front surface of the display. In other examples, such as those described below, the optical imaging system can be configured to obtain an image of a fingerprint of the user 106. In this example, the illumination operation can be instructed by the optical imaging system once the finger of the user 106 is detected by a touch input sensor or a force input sensor. It may be appreciated that these foregoing examples are not exhaustive and that, in other embodiments, other configurations of an optical imaging system can be configured for other imaging purposes and, as such, any suitable implementation-specific method of triggering an illumination operation of an imaging subject can be used.

As noted above, and for simplicity of description, the embodiments that follow reference an optical imaging system 110 configured to image a fingerprint of a user. In these constructions, the electronic device 100 can obtain an image of the fingerprint of the user 106 in response to a touch or force input sensor detecting at least one contact area and, correspondingly, the display performing an illumination operation. Collectively, these operations are referred to herein as a “fingerprint imaging operation.”

In some embodiments, the optical imaging system 110 of the electronic device 100 illuminates, or otherwise causes to be illuminated, the finger of the user 106 during a fingerprint imaging operation with light in the visible wavelength band (e.g., green light, blue light, and so on). Light in the visible wavelength band may be selected to maximize reflection of light from an external surface of the finger of the user 106, thereby minimizing or eliminating remittance reflections (e.g., light at least partially reflected and diffused by the subsurface layers of the user's skin) that may otherwise be received by the optical imaging system as noise.

In some embodiments, the optical imaging system 110 instructs the display of the electronic device 100 to illuminate a region of the display below the finger of the user 106, as detected by the input sensor of the electronic device 100, with visible wavelength light. In other examples, the optical imaging system 110 instructs the display to illuminate a perimeter of the user's finger with visible wavelength light. In some examples, the optical imaging system 110 of the electronic device 100 instructs the display to illuminate discrete portions of the finger of the user 106 in sequence or in a particular pattern with visible wavelength light at one or more multiple frequencies or discrete bands.

In view of the preceding examples, it may be appreciated that illumination of the finger of the user 106 with visible wavelength light during a fingerprint imaging operation can occur in a number of suitable ways. For example, in some cases, the optical imaging system of the electronic device 100 illuminates the user's finger with pulsed (continuous or discrete) or steady light in the visible wavelength band. In other examples, the optical imaging system of the electronic device 100 illuminates the finger of the user 106 with visible wavelength light emitted with a particular modulation pattern or frequency.

In further examples, the optical imaging system 110 of the electronic device 100 illuminates the finger of the user 106 by alternating between frequencies or bands of light within the visible wavelength band at a particular frequency, modulation, pulse pattern, waveform and so on.

In still other examples, the optical imaging system 110 instructs the display of the electronic device 100 to illuminate the finger of the user 106 while the active display area 104 of the display of the electronic device 100 also renders a visible-light image. In other words, from the perspective of the user 106, the portion(s) of the display below the fingerprint may not be specially or differently illuminated from other portions of the display; the display can continue to render whichever static or animated image or series of images appeared on the display prior to the user touching the display.

In still further examples, while the optical imaging system 110 and the display are performing a fingerprint imaging operation, the display of the electronic device 100 can locally increase or decrease brightness below the user's finger, can locally increase or decrease contrast below the user's finger, can locally increase or decrease saturation below the user's finger, and so on.

In other examples, the optical imaging system 110 of the electronic device 100 need not trigger an illumination operation of the finger of the user 106 with only visible wavelength light. For example, the optical imaging system may also be configured to illuminate the finger of the user 106 with infrared light in order to detect or otherwise determine the user's pulse or blood oxygen content. In some cases, the optical imaging system 110 is configured to perform a fingerprint imaging operation substantially simultaneously with an operation to detect the pulse of the user 106 to increase confidence that the fingerprint image obtained by the fingerprint imaging operation corresponds to a living specimen.

It may be appreciated that the foregoing description of FIG. 1A, and the various alternatives thereof and variations thereto, are presented, generally, for purposes of explanation, and to facilitate a thorough understanding of various possible configurations of an electronic device incorporating a display stack suitable for through-display imaging, such as described herein. However, it will be apparent to one skilled in the art that some of the specific details presented herein may not be required in order to practice a particular described embodiment, or an equivalent thereof.

For simplicity of description and illustration, FIG. 1B is provided. This figure depicts a simplified block diagram of the electronic device of FIG. 1A showing various operational and structural components that can be included in an electronic device configured to through-display imaging such as described herein.

In particular, the electronic device 100 includes an input/display stack 104a that can include, or can be positioned below (not shown), a protective outer cover, a cover glass, or other suitable transparent portion of the housing 102 shown in FIG. 1A.

In these examples, the protective outer cover can be positioned over a front surface of the input/display stack 104a, which can include at least a light-emitting layer and a touch input layer. An example light-emitting layer can be implemented with organic light emitting diode display technology or micro light emitting diode display technology.

An example touch input layer includes a flexible or rigid transparent substrate (e.g., glass, plastic, acrylic, polymer materials, organic materials, and so on) with an array of capacitive touch input sensors configured to detect at least one contact area defined when the user 106 touches the front surface of the input/display stack 104a (or the protective outer cover).

As noted with respect to other embodiments described herein, the input/display stack 104a can define an array of discrete light-emitting regions or areas that are independently addressable and controllable, referred to herein as “pixels,” that are disposed onto a transparent or partially transparent substrate.

In particular, as a result of the transparent substrate, inter-pixel regions of the input/display stack 104a can be optically transparent and, thus, at least a portion of light incident to the front surface of the input/display stack 104a can traverse the input/display stack 104a from the front surface to the back surface. The pixels of the input/display stack 104a can be disposed at a constant pitch or a variable pitch to define a single pixel density or one or more pixel densities.

As noted with respect to other embodiments described herein, the active display area 104 of the display of the electronic device 100, defined by the input/display stack 104a, is positioned at least partially above the optical imaging system, identified in the figure as the optical imaging system 110a. In another, non-limiting, phrasing, the optical imaging system 110a is adhered to or otherwise coupled to an optically-transparent portion (e.g., an imaging aperture) of the rear surface of the input/display stack 104a, aligned with at least one inter-pixel region of the input/display stack 104a through which light incident to the front surface of the input/display stack 104a can pass. As a result of this construction, the optical imaging system 110a can receive light transmitted through inter-pixel regions of the active display area 104 of the display of the electronic device 100.

The optical imaging system 110a can be formed from multiple functional and/or structural layers. In particular, the optical imaging system 110a can be formed onto a rigid or flexible substrate 112 that supports an array of photodiodes 114. The rigid or flexible substrate 112 can be formed from a number of suitable materials and can include any suitable number of layers. Example materials that can be used to form a rigid or flexible substrate 112 of an optical imaging system, such as the optical imaging system 110a, include but are not limited to glass, plastic, acrylic, polyethylene terephthalate, or other polymers, and the like.

The array of photodiodes 114 can be formed onto the rigid or flexible substrate 112 using any suitable process including operations such as, but not limited to, pick and place operations or thin-film masking, and additive manufacturing or subtractive manufacturing operations. In many embodiments, the array of photodiodes 114 are manufactured using a thin-film transistor manufacturing technique which can include, without limitation, operations such as deposition operations, sputtering operations, photoresist coating and/or curing operations, exposure operations, development and/or etching operations, photoresist removal operations, polyamide or other film coating operations, cleaning operations, adhesive coating or deposition operations, adhesive curing operations, filling operations, cutting or singulation operations, and so on.

The array of photodiodes 114 can be positioned relative to an array of collimators 116. As noted, above, a collimator array, such as the array of collimators 116, can be formed in any suitable manner from a number of suitable materials and is configured to narrow a field of view of at least one photodiode of the array of photodiodes 114. In other words, a collimator such as described herein is an example of a narrow field of view optical filter that passes light directed substantially parallel to a central axis of the narrow field of view filter and blocks (e.g., reflects or otherwise absorbs) light directed not substantially parallel to the central axis of the narrow field of view filter.

In one embodiment, the array of collimators 116 is implemented as an array of columnar apertures defined through an optically opaque layer (e.g., an ink layer, a metal backing layer, a reflective layer, and so on). In these examples, the columnar apertures can have any suitable lateral cross-section (e.g., a cross-section perpendicular to a central axis of a respective aperture). An example cross-section of a columnar aperture, such as described herein, is a circular cross-section, a square cross-section, a polygonal cross-section, and the like. In some cases, the columnar apertures can be filled with an optically transparent material, such as plastic or acrylic. Thereafter, the filler material can be cured.

As with the array of photodiodes 114, the array of collimators 116 can be formed onto the array of photodiodes 114 using any suitable process including operations such as, but not limited to, pick and place operations, lamination operations, thin-film transistor masking, or additive manufacturing or subtractive manufacturing operations.

In many embodiments, as with the array of photodiodes 114, the array of collimators 116 are manufactured using a thin-film transistor manufacturing technique which can include, without limitation, operations such as deposition operations, sputtering operations, photoresist coating and/or curing operations, exposure operations, development and/or etching operations, photoresist removal operations, polyamide or other film coating operations, cleaning operations, adhesive coating or deposition operations, adhesive curing operations, filling operations, cutting or singulation operations, and so on. In many cases, the operations associated with forming the array of photodiodes 114 can be performed prior to operations associated with forming the array of collimators 116. In this manner, the array of collimators 116 can be precisely aligned with the array of photodiodes 114.

In some cases, a single collimator of the array of collimators 116 is disposed above, and/or formed onto, a single photodiode of the array of photodiodes 114. More particularly, a respective collimator may have substantially the same cross-sectional area as a photosensitive area of the respective photodiode. More generally, in some embodiments, the array of collimators 116 can be disposed and/or formed with a one-to-one relationship relative to the array of photodiodes 114. In other embodiments, multiple collimators can be positioned above a single photodiode. In other words, in some embodiments, the array of collimators 116 can be disposed and/or formed with a many-to-one relationship relative to each photodiode of the array of photodiodes 114.

The array of collimators 116 can be positioned relative to an array of microlenses 118. As noted above, a microlens array, such as the array of microlenses 118, can be formed in any suitable manner from a number of suitable materials and are configured to direct and/or otherwise focus light incident thereto into a respective one collimator of the array of collimators 116. In other words, a microlens such as described herein is an example of an optical adapter configured to direct light in a particular direction or focus light to a particular focal point. For simplicity of description, embodiments described herein reference concave microlenses; however, it may be appreciated that this is merely one example of a microlens shape and that, in other embodiments, other lens shapes may be possible or preferred.

In one embodiment, each of the array of microlenses 118 is implemented as an array of concave lenses aligned with and disposed over a respective one collimator of the array of collimators. In many embodiments, a central axis of each respective microlens is precisely aligned with a central axis of the respective collimator over which the microlens is disposed and/or formed. In other cases, a central axis of a microlens can be shifted relative to a central axis of the respective collimator; in these examples, the microlens can serve to focus light and, additionally, may serve a beam directing purpose. These examples are not exhaustive; in other examples, other lens alignments and configurations may be used.

In many cases, each microlens of the array of microlenses 118 is formed to the same geometry and to take substantially the same shape. However, this is merely one example. In other embodiments, different lenses of the array of microlenses 118 can take different shapes, alignments, sizes, focal lengths, and so on.

As with the array of collimators 116, the array of microlenses 118 can be formed onto the array of collimators 116 using any suitable process including operations such as, but not limited to, pick and place operations, lamination operations, thin-film transistor masking, or additive manufacturing or subtractive manufacturing operations.

In many embodiments, as with the array of collimators 116 and the array of photodiodes 114, the array of microlenses 118 are manufactured using a thin-film transistor manufacturing technique which can include, without limitation, operations such as deposition operations, sputtering operations, photoresist coating and/or curing operations, exposure operations, development and/or etching operations, photoresist removal operations, polyamide or other film coating operations, cleaning operations, adhesive coating or deposition operations, adhesive curing operations, filling operations, cutting or singulation operations, and so on. In many cases, the operations associated with forming the array of collimators 116 can be performed prior to operations associated with forming the array of microlenses 118. In other cases, the array of microlenses 118 can be formed in the same process as the array of collimators 116. For example, a filler material used to fill an aperture defining a collimator of the array of collimators can be used to form the respective microlens associated with that collimator. More specifically, the filler material can be “overfilled” such that overflow from filling the aperture can form a curved meniscus that, once cured, can define a microlens of suitable or preferred geometry. In this manner, the array of microlenses 118 can be precisely aligned with the array of collimators 116.

In some cases, a single microlens of the array of microlenses 118 is disposed above, and/or formed onto, a single collimator of the array of collimators 116. More particularly, a respective microlens may have substantially the same area as a cross-sectional area of the respective collimator. More generally, in some embodiments, the array of collimators 116 can be disposed and/or formed with a one-to-one relationship relative to the array of photodiodes 114. In other cases, more than one microlens can be formed over a single collimator (e.g., a many-to-one relationship). In many embodiments, only a single microlens is formed over a single collimator.

As a result of these constructions, light that passes through inter-pixel regions of the input/display stack 104a can be focused by the microlens array 118 into the collimator array 116 which, in turn, can pass light oriented/directed substantially or generally parallel to a central axis thereof onto the photodiode array 114. As a result of this stack-up, the optical imaging system 110a can be configured to collect only light directed substantially normal thereto. More simply, as a result of this construction, the optical imaging system 110a can be configured to capture light reflected from a two-dimensional contact area of a fingerprint of the user 106, in which light absorbed/collected by a single photodiode corresponds to a single pixel of an image of that fingerprint.

In order to measure or determine light collected by each photodiode of the array of photodiodes 114, the substrate 112 may further include one or more electrical traces and/or circuits electrically coupled to each photodiode of the array of photodiodes 114. Such circuits and/or traces can take any suitable topology; example circuit topology can include a pre-amplification stage, an amplification stage, a binning stage, a charge storage stage, a multiplexing stage, a de-multiplexing stage, an addressing stage, and the like.

The substrate 112 can be electrically coupled to a flexible circuit 120 that conductively and communicably couples the circuits and/or traces defined on the substrate 112 to a general or special purpose processor or circuit of the electronic device 100, identified as the processor 122. The processor 122 can be any suitable processor or circuitry capable of performing, monitoring, or coordinating one or more processes or operations of the electronic device 100. The processor 122 can be any suitable single-core or multi-core processor capable to execute instructions stored in a memory (not shown) to instantiate one or more classes or objects configured to interface with an input or output of one or more of the optical imaging system 110a and/or the input/display stack 104a. In some examples, the processor 122 may be a dedicated processor associated with one or more of the optical imaging system 110a, the input/display stack 104a, and/or the electronic device 100. In other cases, the processor 122 may be a general purpose processor.

In still other embodiments, the electronic device 100 can include one or more optional optical components. The optional optical components are typically positioned between layers of the optical imaging system 110a and the input/display stack 104a and can include, but may not be limited to: one or more lenses, filters, mirrors, actuators, apertures, irises, flash elements, narrow field of view filters, collimators, flood illuminators, infrared cut filters, ultraviolet cut filters, or other accessory optical elements, or combinations thereof.

Accordingly, generally and broadly in view of FIGS. 1A-1B, it is understood that an electronic device including a display suitable for through-display imaging can be configured in a number of ways. For example, although the electronic device 100 is depicted as a cellular phone, it may be appreciated that other electronic devices can incorporate a display stack such as described herein including, but not limited to: tablet devices; laptop devices; desktop computers; computing accessories; peripheral input devices; vehicle control devices; mobile entertainment devices; augmented reality devices; virtual reality devices; industrial control devices; digital wallet devices; home security devices; business security devices; wearable devices; health devices; implantable devices; clothing devices; fashion accessory devices; and so on.

Further it is appreciated that, beyond the components depicted in FIGS. 1A-1B, the electronic device can also include one or more processors, memory, power supplies and/or batteries, network connections, sensors, input/output ports, acoustic elements, haptic elements, digital and/or analog circuits for performing, supervising, and/or coordinating one or more tasks of the electronic device 100, and so on. For simplicity of illustration, the electronic device 100 is depicted in FIGS. 1A-1B without many of these elements, each of which may be included, partially and/or entirely, within the housing 102 and may be operationally or functionally associated with, or coupled to, the display of the electronic device 100.

Further, although the electronic device 100 includes only a single rectangular display, it may be appreciated that this example is not exhaustive. In other embodiments, an electronic device can include, or may be communicably coupled to, multiple displays, one or more of which may be suitable for through-display imaging. Such accessory/auxiliary displays can include, but may not be limited to: secondary monitors; function row or keyboard key displays; wearable electronic device displays; peripheral input devices (e.g., trackpads, mice, keyboards, and so on) incorporating displays; digital wallet screens; and so on. Similarly, a rectangular display may not be required; other embodiments are implemented with displays taking other shapes, including three-dimensional shapes (e.g., curved displays).

Similarly, although the display described in reference to the electronic device 100 is a primary display of an electronic device, it is appreciated that this example is not exhaustive. In some embodiments, a display stack can define a low-resolution auxiliary display, such as a monochromatic display or a greyscale display. In other cases, a display stack can define a single-image display, such as a glyph or icon. In one specific example, a power button for an electronic device can include a button cap incorporating a display such as described herein. The display can be configured to selectively display a power icon and/or a limited set of icons or glyphs associated with one or more functions the button may be configured to perform, or one or more configurable options the button is associated with (e.g., power options, standby options, volume options, authentication options, digital purchase options, user authentication options, and so on). In these examples, a limited-purpose, auxiliary, or secondary display can be configured to have partial transparency or translucency, such as described herein, to facilitate through-display imaging.

Thus, it is understood that the foregoing descriptions of specific embodiments are presented for the purposes of illustration and description. These descriptions are not exhaustive nor intended to limit the disclosure to the precise forms recited herein. To the contrary, it will be apparent to one of ordinary skill in the art that many modifications and variations are possible in view of the above teachings. Particularly, it is understood that a display stack suitable for through-display imaging can be constructed and/or assembled in many suitable ways. For example, an optical imaging system, such as described herein, can be formed by assembling or creating layers in a different order and/or with additional layers.

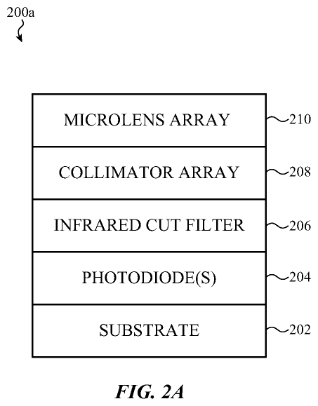

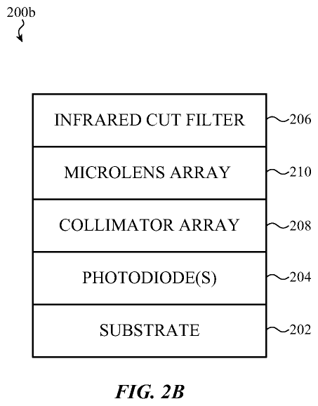

In particular, FIG. 2A depicts an example stack of layers that can cooperate to define an optical imaging system 200a. In this example embodiment, a substrate 202 supports an array of photodiodes 204, as with the embodiment described in reference to FIG. 1B. In this example, an infrared cut filter 206 can be formed over the array of photodiodes 204. The infrared cut filter 206 can be formed from any suitable material configured to absorb and/or reflect at least infrared light so that infrared light does not interfere with imaging operation(s) of the photodiodes 204. As with other layers of other embodiments of an optical imaging system, such as described herein, the infrared cut filter 206 can be formed, disposed, cured, and/or otherwise manufactured according to thin-film transistor manufacturing techniques. Disposed or otherwise formed over the infrared cut filter 206 is an array of collimators 208 below a microlens array 210.

In this embodiment, when the optical imaging system 200a is coupled to (e.g., via an adhesive having a different refractive index than the microlens array 210) a rear surface of a display stack (and/or below an imaging aperture of a display stack), light incident to a front surface of that display stack that passes through inter-pixel regions of that display stack can exit the rear surface of the display stack, can be focused by the microlens array 210 into the collimator array 208, which in turn can filter said light based on orientation and direction of that light (e.g., only light within an acute angle of a central axis of a collimator passes through the collimator; all other light is reflected or absorbed by the collimator) and can direct the filtered light through the infrared cut filter 206 passing only orientation-filtered visible light such that at least one photodiode of the array of photodiodes 204 can absorb said light.

In other cases, an optical imaging system can be arranged in another manner. FIG. 2B depicts another example optical imaging system 200b in which the infrared cut filter 206 is disposed above the microlens array 210, in turn above the collimator array 208, in turn above the photodiode array 204 disposed on the substrate 202.

The preceding example constructions of an optical imaging system are not exhaustive. In some embodiments, other optical filters can be an infrared pass filter, a color filter, a variable color filter (e.g., a liquid crystal filter), a polarization filter, and so on. In other cases, an optical filter can be positioned elsewhere in the stack. More simply, it may be appreciated that other example configurations are possible in view of the various example embodiments described herein.

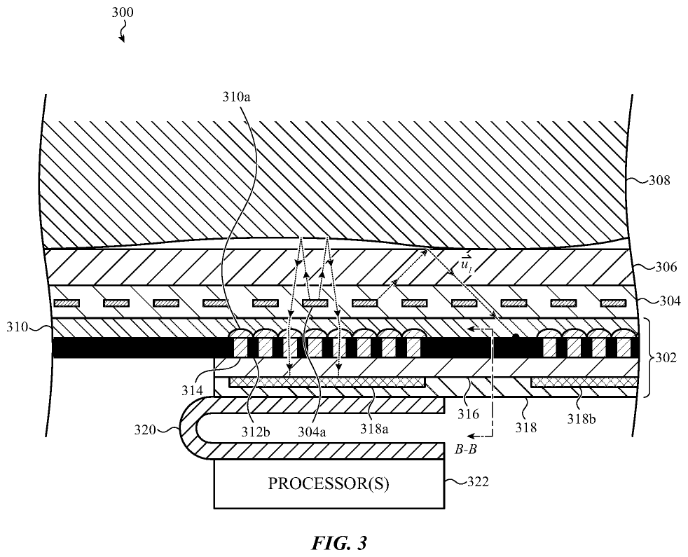

For example, FIG. 3 depicts another example cross-section of an optical imaging system coupled to a display stack, such as described herein. In particular, the optical imaging system 300 includes an optical imaging stack-up 302 positioned below a light-emitting layer 304 of a display. The light-emitting layer 304 is positioned below a protective outer cover 306 that can enclose and protect the light-emitting layer 304 and the optical imaging system 300. In addition, the protective outer cover 306 can define an input surface to receive a touch of a user 308.

In this manner, in response to the user's touch to the input surface (which may be detected by a touch input sensor, such as described above) the optical imaging system 300 can instruct the light-emitting layer 304 to initiate an illumination operation to illuminate the user's finger. In particular, the light-emitting layer 304 can provide power to at least one pixel, such as the pixel 304a, to cause the pixel 304a to emit light through a front surface of the light-emitting layer 304, through the protective outer cover 306, and toward the user 308. The user's skin may reflect at least a portion of the light emitted by the pixel 304a, which may redirect said reflected light back toward the protective outer cover 306.

At least a portion of this reflected light can pass through the protective outer cover 306, and through an interpixel region of the light-emitting layer 304 to exit a rear surface of the light-emitting layer 304 into an adhesive layer 310. At least a portion of this light can be focused by at least one microlens of a microlens array of the optical imaging stack-up 302 (one of which is identified as the microlens 310a of the optical imaging stack-up 302) protruding into the adhesive layer 310. At least a portion of the focused light can be directed into at least one collimator of an array of collimators defined through an opaque layer 312, which is configured to block light, including environmental light, from passing through the display (e.g., FIG. 3 includes one example light ray u₁ blocked by the opaque layer 312). The opaque layer 312 of the display may be included to increase apparent contrast of the active display area and, additionally, to provide a structural layer through which the array of collimators is formed. An example collimator of the optical imaging stack-up 302 is identified as the collimator 314. At least a portion of the portion of the light passing through the collimator array can be filtered by an infrared cut filter 316 of the optical imaging stack-up 302. At least a portion of the light passing through the infrared cut filter 316 can be absorbed by a photodiode 318a defined onto and/or into a thin-film transistor substrate 318.

The photodiode 318a can be conductively coupled to at least one electrical trace defined on the thin-film transistor substrate 318 which, in turn, can be coupled to a flexible substrate 320 that communicably and conductively couples the photodiode 318a (and, additionally, other photodiodes 318b disposed on the thin-film transistor substrate 318) to a processor 322.

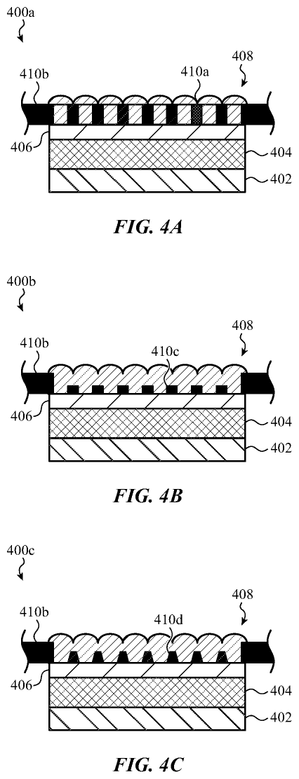

This example cross-section of an optical imaging system is not exhaustive of the various configurations and layouts of an optical imaging system, such as described herein. For example, FIGS. 4A-4C depict different example configurations of imaging optics, such as collimators and microlenses, that can be used with an optical imaging system, such as described herein, that can be used with the optical imaging system of FIG. 3. For example, the embodiments shown in FIGS. 4A-4C can be viewed along line B-B as shown in FIG. 3. In particular, FIG. 4A depicts an optical imaging system 400a including a substrate 402 that supports an array of photodiodes 404 below an infrared cut filter 406, which may be optional. Above the infrared cut filter 406, an imaging optics layer 408 can be formed.

In this example, the imaging optics layer 408 includes an array of collimators formed by initially disposing an optically opaque layer over the infrared cut filter 406. Once the opaque layer is formed, an array of apertures can be formed or otherwise defined through that layer over the array of photodiodes 404. Thereafter, the apertures can be filled with an optically transparent curable material to define a set or array of imaging optics, each including a convex microlens (one of which is identified as the microlens 410a) and a collimator (one of which is identified as the collimator 410b).

The imaging optics defined by the imaging optics layer 408 can take a number of suitable shapes, cross-sections, and geometric designs. For example, in some embodiments, a pitch separating microlenses and collimators can be larger than that shown in FIG. 4A. In other examples, a variable pitch between imaging optics can be used. For example, collimators and microlenses can be disposed in groups; a first group or array of imaging optics disposed at a first pitch can be separated from a second group or array of imaging optics disposed at the first or a different, second pitch. In these embodiments, different number arrangements of groups of imaging optics can be disposed in any suitable pattern or arrangement.

Similarly, a convexity of a microlens, or, more generally, a shape of the lens, can vary from embodiment to embodiment. Similarly, in some embodiments, a microlens may be separated by a distance from an associated collimator. For example, FIG. 4B depicts an optical imaging system 400b in which the imaging optics layer 408 includes a reduced-height collimator 410c. A person of skill in the art may appreciate that different height(s) of collimator sidewalls can confer different optical and/or filtering properties; different embodiments may be implemented in different ways.

In still other embodiments, collimator sidewalls need not be perpendicular to other layers of the optical imaging system. For example, an optical imaging system 400c depicted in FIG. 4C includes a trapezoidal collimator sidewall.

It may be appreciated the previous examples are not exhaustive of the different configurations of imaging optics that can be formed with an optical imaging system, such as described herein. In other embodiments, other variations are possible.

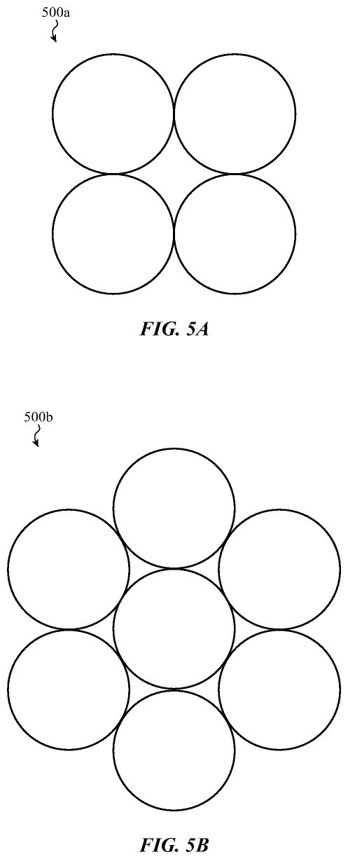

For example, imaging optics, and, in particular, microlenses, of an optical imaging system can be distributed in a number of possible ways in various embodiments. For example, FIG. 5A depicts a first arrangement of microlenses 500a that distributes microlenses in a grid pattern. In another example, FIG. 5B depicts a second arrangement of microlenses 500b that distributes microlenses in a circular packing arrangement. In other cases, microlenses of the same array can be formed with different sizes or dimensions, may partially overlap, or may be separated at a constant or variable pitch.

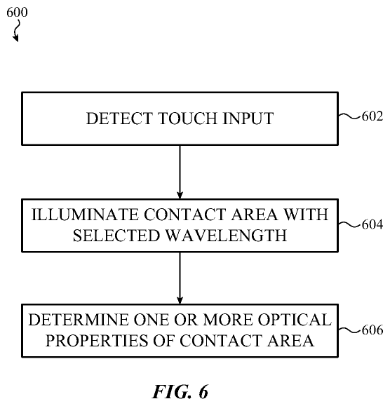

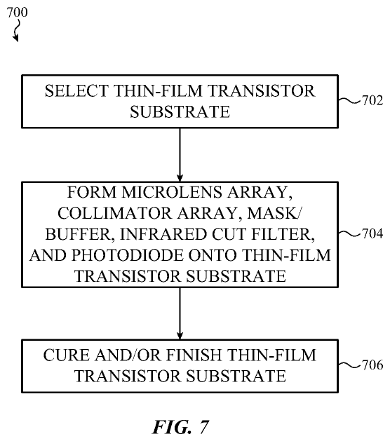

Generally and broadly, FIGS. 6 and 7 depict simplified flow charts corresponding to various ordered and/or unordered operations of methods described herein. It may be appreciated that these simplified examples may be modified in a variety of ways. In some examples, additional, alternative, or fewer operations than those depicted and described may be possible.

FIG. 6 is a simplified flow chart depicting example operations of a method of capturing an image of an object touching a display with an optical imaging system disposed behind that display, such as described herein. The method can be performed, in whole or in part, by a processor or circuitry of an electronic device such as described herein.

The method 600 includes operation 602 in which a touch to a display of an electronic device is detected. The initial touch can be detected using any suitable sensor or combination of sensors including but not limited to touch sensors and force sensors. Example touch sensors include, but are not limited to: capacitive touch sensors; optical touch sensors; resistive touch sensors; acoustic touch sensors; and so on. Example force sensors include, but are not limited to: capacitive force sensors; resistive force sensors; piezoelectric force sensors; strain-based force sensors; inductive force sensors; and so on.

Once a touch is detected at operation 602, the method 600 continues to operation 604, in which a contact area of the detected touch is illuminated with visible wavelength light. As noted with respect to other embodiments described herein, the illumination of the contact centroid and/or contact area can be performed in any suitable manner including, but not limited to: a specific/selected modulation of light; a specific/selected pattern (e.g., linear sweep, radial sweep, radial expansion, and so on); and so on or any combination thereof.

The method 600 also includes operation 606 in which one or more optical properties of the contact area are determined. In one example, a fingerprint image is captured by the optical imaging system of the electronic device. As noted with respect to other embodiments described herein, the operation of capturing an image of a fingerprint (or, more generally, an image of an object in contact with the display at operation 602) can include one or more filtering operations such as: spatial filtering (e.g., point-source filtering, beam-forming, and so on); thresholding; de-skewing; rotating; and so on.

FIG. 7 is a simplified flow chart depicting example operations of a method of manufacturing an optical imaging system, such as described herein. In particular, the method 700 includes operation 702 in which a thin-film transistor substrate is selected. Thereafter, the method 700 continues to operation 704 in which various functional and/or structural layers of the optical imaging system can be formed. For example, a microlens array, a collimator array, a masking layer (associated with the collimator array), an infrared cut filter, and a photodiode array can all be formed onto the thin-film transistor substrate. Thereafter, at operation 706, the various layers formed at operation 704 can be cured or otherwise finished.

One may appreciate that, although many embodiments are disclosed above, the operations and steps presented with respect to methods and techniques described herein are meant as exemplary and accordingly are not exhaustive. One may further appreciate that alternate step order or, fewer or additional operations, may be required or desired for particular embodiments.

Although the disclosure above is described in terms of various exemplary embodiments and implementations, it should be understood that the various features, aspects, and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

Further, the present disclosure recognizes that personal information data, including biometric data, in the present technology, can be used to the benefit of users. For example, the use of biometric authentication data can be used for convenient access to device features without the use of passwords. In other examples, user biometric data is collected for providing users with feedback about their health or fitness levels. Further, other uses for personal information data, including biometric data, that benefit the user are also contemplated by the present disclosure.

The present disclosure further contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure, including the use of data encryption and security methods that meets or exceeds industry or government standards. For example, personal information from users should be collected for legitimate and reasonable uses of the entity and not shared or sold outside of those legitimate uses. Further, such collection should occur only after receiving the informed consent of the users. Additionally, such entities would take any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices.

Despite the foregoing, the present disclosure also contemplates embodiments in which users selectively block the use of, or access to, personal information data, including biometric data. That is, the present disclosure contemplates that hardware and/or software elements can be provided to prevent or block access to such personal information data. For example, in the case of biometric authentication methods, the present technology can be configured to allow users to optionally bypass biometric authentication steps by providing secure information such as passwords, personal identification numbers, touch gestures, or other authentication methods, alone or in combination, known to those of skill in the art. In another example, users can select to remove, disable, or restrict access to certain health-related applications collecting users' personal health or fitness data.

What is claimed is:

1. An optical sensing system comprising:
a first substrate formed from a transparent material;
a light-emitting element formed onto the first substrate and configured to emit light normal to a first surface of the first substrate; and
a second substrate coupled to a second surface of the first substrate that is opposite the first surface, the second substrate comprising:
a photodiode formed onto the second substrate and configured to collect light normal to the second surface;
a collimator formed onto, and aligned with, the photodiode, positioned between the photodiode and the second surface; and
a microlens formed onto, and aligned with, the collimator and configured to focus light incident to the microlens into the collimator, the microlens positioned between the collimator and the second surface; wherein:
at least a portion of light emitted from the light-emitting element reflects from a surface of an object proximate to the first substrate, thereby becoming reflected light; and
the photodiode is configured to absorb at least a portion of the reflected light that passes through the first substrate, the microlens, and the collimator.

2. The optical sensing system of claim 1, wherein the photodiode, the collimator, and the microlens are formed by a thin-film transistor manufacturing process.

3. The optical sensing system of claim 1, further comprising an infrared cut filter disposed between the collimator and the photodiode.

4. The optical sensing system of claim 1, further comprising an infrared cut filter disposed between the collimator and the microlens.

5. The optical sensing system of claim 1, further comprising an infrared cut filter disposed between the microlens and the second surface.

6. The optical sensing system of claim 1, further comprising an infrared cut filter disposed over the first surface.

7. The optical sensing system of claim 1, wherein the first substrate comprises a portion of a display.

8. The optical sensing system of claim 1, wherein:
the light-emitting element is a first light-emitting element; and
the first substrate comprises an array of light-emitting elements comprising the first light-emitting element.

9. The optical sensing system of claim 1, wherein the object comprises a finger.

10. An electronic device configured to capture an image of a portion of an object touching a surface of the electronic device, the electronic device comprising:
a transparent outer cover defining an interface surface operable to receive a touch from the object;
a light-emitting layer positioned below the transparent outer cover and comprising:
a first thin-film transistor layer comprising a transparent substrate; and
an array of pixels disposed in a pattern on the transparent substrate and configured to emit light through the transparent outer cover to illuminate a contact area defined by a portion of the object that is in contact with the interface surface during the touch; and
an optical imaging sensor coupled to a lower surface of the first thin-film transistor layer and comprising:
a second thin-film transistor layer comprising a conductive trace;
a photosensitive element coupled to the second thin-film transistor layer and electrically coupled to the conductive trace;
an infrared cut filter coupled to the photosensitive element and configured to reflect and/or absorb infrared light passing through the transparent substrate between pixels of the array of pixels;
a collimator array formed over the infrared cut filter and configured to narrow a field of view of the photosensitive element; and
a microlens array formed over the collimator array, each respective microlens of the microlens array configured to focus light incident to a respective microlens into a respective collimator of the collimator array, the microlens array coupled to the lower surface of the first thin-film transistor layer by an adhesive; wherein:
at least a portion of light emitted from the light-emitting layer reflects from the contact area, passes through the transparent substrate between pixels of the array of pixels, is focused into a respective one collimator of the collimator array by a respective one microlens of the microlens array, and is absorbed by the photosensitive element.

11. The electronic device of claim 10, wherein the object is a finger and the at least the portion of light emitted from the light-emitting layer and absorbed by the photosensitive element is used to construct a fingerprint image.

12. The electronic device of claim 10, wherein the light-emitting layer is a display.

13. The electronic device of claim 12, wherein the display is one of an organic light-emitting diode display or a micro light-emitting diode display.

14. The electronic device of claim 10, wherein the collimator array comprise:
an opaque layer disposed over the photosensitive element; and
an array of apertures defined through the opaque layer and each aligned along a common axis.

15. The electronic device of claim 14, wherein the opaque layer comprises ink.

16. The electronic device of claim 14, wherein the common axis is parallel to normal to the photosensitive element.

17. The electronic device of claim 10, wherein the photosensitive element is a photodiode.

18. The electronic device of claim 10, wherein the second thin-film transistor layer is optically transparent.

19. The electronic device of claim 10, further comprising a touch-sensitive layer disposed between the transparent outer cover and the light-emitting layer.

20. The electronic device of claim 19, wherein the touch-sensitive layer comprises a capacitive touch sensor.

21. The electronic device of claim 10, wherein:
the adhesive comprises a first material having a first refractive index; and
the microlens array comprise a second material having a second refractive index;
wherein:
the first refractive index is different from the second refractive index.

22. An optical sensing system for capturing light incident to a display of an electronic device, the optical imaging system comprising:
a thin-film transistor substrate coupled to a rear surface of the display opposite a front surface of the display from which light is emitted by the display;
an array of photosensitive elements each coupled to the thin-film transistor substrate positioned between the thin-film transistor substrate and the rear surface of the display, and oriented to collect light incident to the front surface of the display;
a collimator disposed over a photodiode and between the photodiode and the rear surface of the display; and
a microlens disposed over the collimator and positioned between the collimator and the rear surface; wherein:
light emitted from the display is reflected from a finger proximate to the front surface of the display; and
at least a portion of the reflected light passes through the display, the microlens, and the collimator, and is collected by the photodiode.

23. The optical sensing system of claim 22, further comprising:
a flexible circuit communicably coupled to a processor of the electronic device; wherein the thin-film transistor substrate is coupled to the flexible circuit;

24. The optical sensing system of claim 22, wherein:
the microlens has a first width; and
the collimator has a second width different from the first width.

25. The optical sensing system of claim 22, wherein the microlens is aligned with a central axis of the collimator.

26. An optical imaging system, such as described herein.

27. A fingerprint imaging system for imaging fingerprints through a display, such as described herein.

28. A fingerprint imaging system formed by thin-film transistor manufacturing processes for imaging fingerprints through a display, such as described herein.

29. An electronic device including a fingerprint imaging system formed by thin-film transistor manufacturing processes for imaging fingerprints through a display, such as described herein.

30. The electronic device of claim 29, wherein the display is an organic light-emitting diode display or a micro lightemitting diode display.
